(19) United States
(12) Patent Application Publication
(10) Pub. No.: US 2025/0226346 A1
(43) Pub. Date: Jul. 10, 2025

(54) POWER SEMICONDUCTOR, MOLDED MODULE, AND METHOD

(71) Applicant: Robert Bosch GmbH, Stuttgart (DE)

(72) Inventor: Martin Fleischmann, Herrenberg (DE)

(21) Appl. No.: 18/700,226

(22) PCT Filed: Sep. 30, 2022
(86) PCT No.: PCT/EP2022/077337

§ 371 Date: Apr. 25, 2024

(30) Foreign Application Priority Data
Oct. 14, 2021 (DE) 10 2021 211 642.6

(51) Int. Cl. H01L 23/00; H01L 23/31

(52) U.S. Cl. CPC H01L 24/29; H01L 23/3135; H01L 24/27; H01L 24/30; H01L 24/32; H01L 2224/27602; H01L 2224/279; H01L 2224/29018; H01L 2224/29082; H01L 2224/3003; H01L 2224/30051; H01L 2224/32227

(57) ABSTRACT

A power semiconductor having a power semiconductor switch. The power semiconductor switch is cuboidal and has a switching path terminal on one side, a further switching path terminal on a side opposite thereto, and a control terminal for switching the power semiconductor switch. The control terminal is formed at a distance from the switching path terminal, on the side of the switching path terminal. The power semiconductor has a control contact element, connected to the control terminal, for the control terminal, a contact element connected to the switching path terminal, and a molded housing. A part of the surface is covered by the molding compound. An outward-facing contact surface of the contact elements can be contacted from the outside. The power semiconductor switch has a further switching path terminal which can be contacted from the outside directly.

### FIELD

The present invention relates to a power semiconductor, preferably a power transistor for a commutation cell, in particular a commutation cell for an inverter. The power semiconductor has a power semiconductor switch, in particular a power transistor. The power semiconductor switch is flat, in particular cuboidal, and has a switching path terminal, in particular a source terminal, on one side. The power semiconductor switch has a further switching path terminal, in particular a drain terminal, on a side opposite thereto. The power semiconductor switch also has a control terminal, in particular a gate terminal, for switching the power semiconductor switch, wherein the control terminal is formed at a distance from the switching path terminal, on the side of the switching path terminal. For the control terminal, the power semiconductor has a control contact element connected to the control terminal and a contact element connected to the switching path terminal. The power semiconductor also has a molded housing, wherein a part of the surface, in particular lateral surfaces and/or at least partially the side with the switching path terminal and the control terminal, is covered by the molding compound, wherein an outward-facing contact surface of the contact elements, in particular of the control contact element and of the contact element, can be contacted from the outside.

### BACKGROUND INFORMATION

German Patent Application No. DE 10 2016 225 654 A1 describes a power module which has a housing formed by a casting compound.

### SUMMARY

According to the present invention, the power semiconductor switch, in particular power transistor, of the power semiconductor of the type mentioned at the outset has a further switching path terminal, in particular a drain terminal, which can be contacted from the outside, in particular directly.

The further switching path terminal, in particular drain terminal, which is thus free of molding compound, can thus be advantageously soldered or sintered to a circuit carrier. The switching path terminal, in particular source terminal, which is arranged by means of the contact element on a side of the power semiconductor switch that is designed for electrical contacting, in particular wire bonding, soldering, or sintering, is thus further away from the further switching path terminal, in particular drain terminal, by means of the molding compound along a periphery of the power semiconductor switch, so that a creepage path for a voltage formed between the switching path terminals cannot be discharged over a short distance between the switching path terminals on the in particular electrically conductive side of the power semiconductor switch if the power semiconductor switch is blocked.

This is because it has been found that power transistors which are cuboidal and in particular housingless, also referred to as bare dies, can be connected to a circuit carrier and can be embedded in molding compound to form a power module. However, cavities or gaps, in which air can be present and in which a creepage path for a short-circuit discharge can form between the switching path terminals, can form in the molding compound. With the power transistor housed in this way by means of the molding compound, a possible creepage path in the case of a gap-containing encapsulation of the power transistor in a power module can be extended and the probability of the creepage path forming can be reduced to the extent that a molding compound embedding the housed power transistor can adhere well to the molding compound of the housing of the power transistor.

The power transistor is preferably a field-effect transistor, in particular a MOSFET (MOS=metal oxide semiconductor), a MISFET (MIS=metal-insulated semiconductor), an IGBT (insulated-gate bipolar transistor), or a HEMT (high-electron-mobility transistor).

In a preferred embodiment of the present invention, a molded body forming the molded housing is flush with the contact surface of the contact elements. Advantageously, the power transistor can thus be produced in an injection molding method or casting method at low cost. In another embodiment, the contact elements protrude from the molded body. Advantageously, the contact elements, and thus the contact surfaces, can be reached in a simple manner from a top side of the power transistor, for example by wire bonding or by resistance welding.

In a preferred embodiment of the power semiconductor of the present invention, the contact surfaces of the contact elements have, on the contactable outer side, a greater distance from one another than the terminal surfaces of the terminals formed on the transistor, in particular the terminal surfaces of the control terminal and of the switching path terminal.

Advantageously, a distance between the control terminal, in particular a gate terminal, and the switching path terminal, in particular a source terminal, of the power transistor can thus be offset, and the distance can thus be enlarged. Advantageously, the power semiconductor can thus be contacted more simply by means of a bond wire, a bond ribbon, or by soldering or sintering from a side of the transistor that faces away from a circuit carrier. Further advantageously, a larger insulation distance between the terminals of the power semiconductor can be formed in this way.

In a preferred embodiment of the present invention, at least one of the contact surfaces of the contact elements has, on the contactable outer side, a larger, in particular externally contactable, contact surface than the corresponding terminal surface of the terminal formed on the transistor, in particular the terminal surface of the control terminal and/or of the switching path terminal. Advantageously, contact, in particular bond contact, welded contact, sintered terminal or solder terminal, between a connecting wire or a lead frame and the contact element can thus be produced in a simple manner in the transistor. In another embodiment of the present invention, the power semiconductor can be connected to a further circuit carrier, for example an LTCC circuit carrier (LTCC=low temperature cofired ceramics) or a circuit board, in particular a fiber-reinforced epoxy resin circuit board, by means of the bond wire instead of the lead frame or in addition to the lead frame.

In a preferred embodiment of the present invention, the contact elements each comprise copper and/or silver. The contact elements are preferably made of copper, pure copper, or a copper alloy. Advantageously, the contact elements can thus have good electrical conductivity.

In a preferred embodiment of the present invention, the molded body, in particular inner molded body, has a bevel toward one edge on the surface formed for contacting, in particular on the side on which the control terminal and the switching path terminal are formed. Advantageously, after soldering or sintering to the circuit carrier and after bonding, soldering, or sintering the contacts formed on the surface, a molding compound embedding the power transistor can thus flow completely around the power semiconductor. The molding compound embedding the power transistor, which molding compound embeds both the power transistor and the bond wires that contact the power transistor, can thus flow to the solder points or sinter points of the power transistor without cavities or air gaps. In another advantageous embodiment, the contacts are directly contacted by a further circuit carrier. The further circuit carrier is, for example, a ceramic LTCC circuit carrier (LTCC=low temperature cofired ceramics), HTCC circuit carrier (HTCC=high temperature cofired ceramics), a SIP (SIP=system-in package), or a circuit board.

In a preferred embodiment of the present invention, after encapsulation, the power transistor is separated from neighboring power transistors by means of a fan-out method and thus singulated. Advantageously, the power transistor can thus be provided at low cost. Further advantageously, by means of the fan-out method, in which a single power transistor is separated from a matrix of molded power transistors, the side of the power transistors that faces transversely to the terminal surface can be covered with molding compound. As a result, a good insulation distance can be formed between the switching path terminals, in particular even after further encapsulating the power transistors. Further advantageously, the quality of the surfaces of the power transistor can be particularly clean.

An embodiment of the power transistor of the present invention in which only the sides facing transversely to the terminal surfaces are covered with, in particular inner, molding compound can, for example, be produced by a molding tool covering the terminal surfaces.

The present invention also relates to a molded module, in particular a power module, having a power transistor of the type described above. According to an example embodiment of the present invention, the molded module has a circuit carrier and at least one power semiconductor of the type described above.

The power semiconductor is materially connected to the circuit carrier, in particular connected by soldering or by sintering. The power semiconductor, and at least a part of the circuit carrier, is embedded in an, in particular outer, molding compound, wherein the outer molding compound is, preferably, different from the inner molding compound of the molded body of the power semiconductor. Advantageously, the inner molding compound, which embeds the housingless power transistor, can thus be filled to a high degree with thermally conductive particles, in particular ceramic particles, for example aluminum oxide particles, or silicon nitride particles, so that a thermal conductivity of the molding compound embedding the thus embedded power transistor, in particular bare die, can be particularly good. Further advantageously, a coefficient of thermal expansion of the inner molding compound can thus be adapted to the coefficient of expansion of the power transistor.

According to an example embodiment of the present invention, the outer molding compound, which embeds the power transistor thus enclosed with inner molding compound, can advantageously be an, in particular low-viscosity, molding compound, in particular an epoxy resin compound, which has a greater flowability than the inner molding compound and thus can adjoin a lateral surface of the embedded power transistor particularly tightly and without air gaps or cavities, in particular in the case of a power semiconductor produced in the fan-in method, in which lateral surfaces of the power transistor are exposed due to the singulation after the coating of the contact side with inner molding compound.

Preferably, according to an example embodiment of the present invention, the molding compound embedding the power transistor is different from the outer molding compound surrounding it. Through the two-stage molding process formed in this way, the outer molding compound can be formed with lower technical requirements for adhesion to semiconductor material and for adaptation of the thermal expansion and thermal conductivity than the inner molding compound, which directly adjoins a surface of the power transistor that is to be both electrically contacted and cooled.

Preferably, according to an example embodiment of the present invention, the molding compound embedding the power transistor, hereinafter also referred to as the inner molding compound, has a lower emission of alpha rays, in particular contamination by uranium, than the outer molding compound. Preferably, the inner molding compound has alpha-ray-absorbing or alpha-ray-reflecting particles, in particular ceramic particles. Advantageously, the semiconductor can thus be protected against alpha rays at low cost to the extent that only it, as a result of the molding compound embedding the power transistor, has at least one property that protects against alpha rays. The outer molding compound can be formed by an epoxy resin filled with a lower filling degree in comparison.

Preferably, according to an example embodiment of the present invention, the inner molding compound has a coefficient of thermal expansion adapted to the power semiconductor. Advantageously, a graduated coefficient of thermal expansion can thus be formed radially outward from the power semiconductor. For example, the inner molding compound has a coefficient of thermal expansion, also referred to as CTE (CTE=coefficient of thermal expansion), of between 7 and 9 ppm/K, further preferably 8 ppm/K. Preferably, the outer molding compound has a CTE of between 9 and 12 ppm/K, further preferably 10 ppm/K.

The inner molding compound, which contacts the power transistor directly at least on the terminal side or additionally on the side surfaces, preferably has a larger proportion of filling particles, in particular ceramic particles, than the outer molding compound, which embeds the power semiconductor thus premolded with inner molding compound. The ceramic particles are preferably oxide particles, in particular aluminum oxide particles, nitride particles, in particular silicon nitride particles, boron nitride particles, or aluminum nitride particles, carbide particles, in particular silicon carbide particles or boron carbide particles. In another embodiment, the filling particles are at least partially formed by glass particles, preferably spherical silicon dioxide particles.

Further advantageously, according to an example embodiment of the present invention, the inner molding compound can have an adhesion promoter, in particular an adhesion-promoting substance for adhesion to the power semiconductor switch, in particular power transistor. Advantageously, the outer molding compound thus needs to have no or less adhesion promoter than the inner molding compound. The molded power semiconductor can thus advantageously be provided at low cost. The adhesion-promoting substance is preferably a silane-containing or silane-based substance, for example aminosilane or epoxysilane, y-glycidoxypropyltrimethoxysilane, N-B (aminoethyl) y-aminopropyltriethoxysilane, N-phenyl-y-aminopropyltrimethoxysilane and y-mercaptopropyltrimethoxysilane.

In a preferred embodiment of the present invention, the molding compounds, in particular the inner molding compound and the outer molding compound, have a modulus of elasticity different from one another. Further preferably, the modulus of elasticity of the inner molding compound is greater than the modulus of elasticity of the outer molding compound. Advantageously, a gradient of the modulus of elasticity that decreases from the inside to the outside can thus also be formed, so that spontaneous thermal expansions of the thus stepwise embedded power transistor can be well cushioned by the thus formed molding compounds, in which the outer molding compound can yield resiliently to the expansion of the power semiconductor embedded thereby.

The present invention also relates to a method for producing a power semiconductor, in particular a premolded power semiconductor switch, in particular a power transistor of the type described above.

According to an example embodiment of the present invention, in the method, a bridge contact element that electrically bridges the terminals is placed on the terminals of the power semiconductor switch, in particular the control terminal and the switching path terminal, that face away from a circuit carrier, and the bridge contact element is soldered or sintered to the terminals. The power semiconductor switch, together with the bridge contact element, is encapsulated with an, in particular particle-filled, molding compound and thus embedded. In a further step of the method, a part of the bridge contact element, together with a part of the molding compound embedding the power semiconductor switch, is cut off, in particular sawn off, ground off, milled off, or polished, so that separate contact elements are formed on the terminals. Advantageously, small and delicate contact elements can thus be produced on the terminals of the power transistor at low cost.

Preferably, according to an example embodiment of the present invention, the bridge contact element comprises a connecting portion which connects the contact elements and which is severed when a part of the bridge contact element that comprises the connecting portion is cut off, so that the contact elements are separated from one another. Advantageously, the contact elements can thus be connected to the power semiconductor switch and produced at low cost.

In an advantageous design variant of the present invention, several chips are contacted by the bridge contact element. The bridge contact element can thus contact and bridge several chips of a wafer together, which can then be singulated after the connecting portion or connecting portions have been severed.

According to an example embodiment of the present invention, advantageously, several chips or even an entire panel, in particular formed by a semiconductor wafer, can thus be contacted with a larger bridge element, which is designed to contact and bridge the contact surfaces of several neighboring power semiconductor chips.

In an advantageous embodiment of the present invention, a counterplate having several bridge contact elements can thus be provided in a manner corresponding to a wafer and can be placed on the entire wafer in a sintering step in order then to be materially electrically connected, in particular sintered or soldered, to the wafer in a further step.

For example, the sintering material or soldering material on the contact surfaces for contacting the power semiconductor can be applied to the bridge element, or can be transferred from a sintering film to the bridge contact elements by punching.

In a preferred embodiment of the present invention, the contact elements are flush with the molding compound surrounding them. Advantageously, the power semiconductor can thus be produced in a mold by injection molding, or casting, in particular transfer molding.

In a preferred variant of the method, outward-facing contact surfaces of the contact elements are spaced further apart than the contact surfaces of the power semiconductor switch that are respectively contacted on the power semiconductor switch by the contact elements. Advantageously, a distance between the contacts, and thus a dielectric strength of the power semiconductor switch, can thus be improved. Further advantageously, due to the greater distance between the contact surfaces of the contact elements in comparison with the contact surfaces of the power semiconductor switch, the electrical connectivity, in particular the bondability, solderability, or sinterability, of the thus encapsulated power semiconductor switch can be improved.

In a preferred embodiment of the method of the present invention, the power semiconductor switch, in particular the power transistor together with the molded housing, is materially connected, in particular soldered or sintered, to a circuit carrier. In a further method step, the thus produced power semiconductor is contacted with bond wires or by a further circuit carrier, and at least one semiconductor switch half-bridge, and thus a commutation cell for an inverter, is thus formed, in particular with several power transistors. In a further method step, the power semiconductor, together with the circuit carrier, is embedded in an, in particular outer, molding compound, in particular a particle-filled molding compound. Advantageously, a voltage-proof commutation cell can thus be formed. Preferably, the outer molding compound is different from the inner molding compound embedding the power semiconductor switch, in particular power transistor. Preferably, the outer molding compound can have a greater flowability in the uncured state than the inner molding compound. Advantageously, the outer molding compound can thus flow easily around and safely embed the circuit carrier, solder points, and bond wires. Further advantageously, the molded module can thus be provided at low cost.

The present invention is explained in more detail below with reference to figures and further exemplary embodiments. Further advantageous embodiment variants result from a combination of the features disclosed herein.

### BRIEF DESCRIPTION OF THE DRAWINGS

FIG. 1 shows a sectional view of an exemplary embodiment of an, in particular prepackaged, power semiconductor according to the present invention of which the terminals designed for electrical connection are each connected to a contact element that forms an externally contactable terminal in a molded package of the power semiconductor.

FIG. 2 shows a sectional view of an exemplary embodiment of an, in particular prepackaged, power semiconductor according to the present invention of which the terminals designed for electrical connection are each connected to a contact element that forms an externally contactable terminal in a molded package of the power semiconductor, wherein a distance of the externally contactable contact surfaces is enlarged in comparison with the contact surfaces on the power transistor.

FIG. 3 shows a sectional view of an exemplary embodiment of an, in particular prepackaged, power semiconductor of the present invention of which the terminals designed for electrical connection are each connected to a contact element that forms an externally contactable terminal in a molded package of the power semiconductor, wherein a contact surface of the externally contactable contact surfaces is enlarged in comparison with the contact surfaces on the power transistor.

FIG. 4 shows a sectional view of an exemplary embodiment of an, in particular prepackaged, power semiconductor of the present invention of which the terminals designed for electrical connection are each connected to a contact element that forms an externally contactable terminal in a molded package of the power semiconductor, wherein a contact surface of the externally contactable contact surfaces is enlarged by a graduated contact element in comparison with the contact surfaces on the power transistor.

FIG. 5 shows an exemplary embodiment of a power semiconductor of the present invention with a mold-packaged power transistor of which the molded housing formed by a molding compound has a bevel pointing to external terminals.

FIG. 6 shows an exemplary embodiment of a molded module of the present invention, which has a power semiconductor embedded in a molding compound that is different from the molding compound of the power semiconductor.

### DETAILED DESCRIPTION OF EXAMPLE EMBODIMENTS

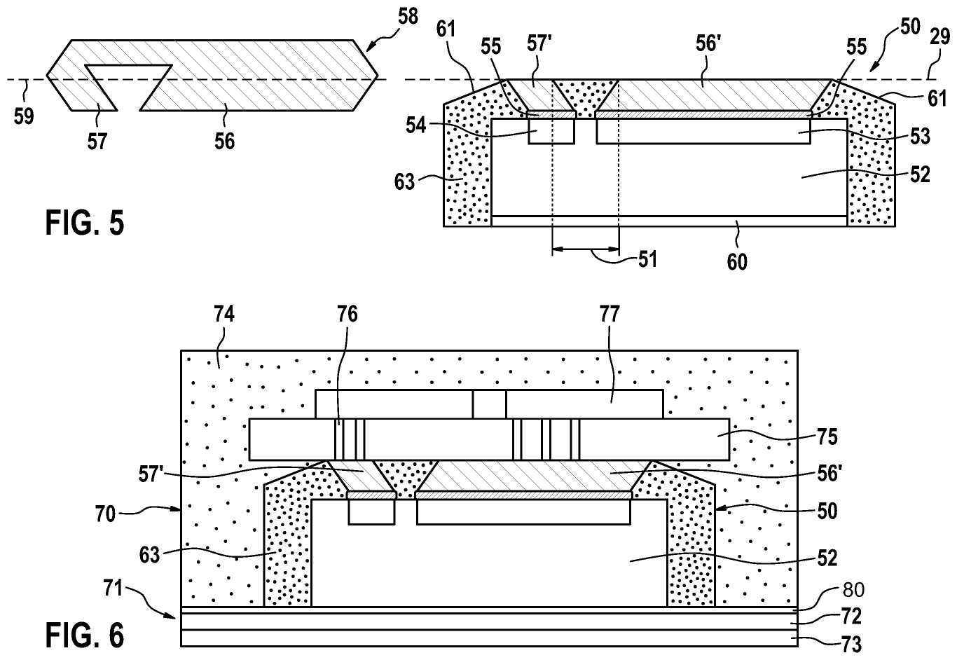

FIG. 1 shows, schematically, a sectional view of an exemplary embodiment of an, in particular prepackaged, power semiconductor 1, in particular a packaged power transistor. The power semiconductor 1 has a power transistor 2, in particular a housingless power transistor, which can, for example, be a field-effect transistor, an IGBT (IGBT=insulated-gate bipolar transistor), or a HEMT (HEMT=high-electron-mobility transistor). The power transistor has a switching path terminal 3, in particular a source terminal, a control terminal 4, in particular a gate terminal, and a further switching path terminal 10, in particular a drain terminal. The further switching path terminal 10 is formed on a side designed for sintering or soldering to a circuit carrier, in particular to a surface region of the power transistor 2, which is cuboidal in this exemplary embodiment. The switching path terminal 3 and the control terminal 4 are each formed on a side opposite thereto. In this exemplary embodiment, the sides of the power transistor extend in parallel with one another. FIG. 1 also shows a bridge contact element 8, which has a contact element 7 for the control terminal 4 and a contact element 6 for contacting the switching path terminal 3, and which are connected to one another by means of a metal bridge. The bridge contact element 8 is thus formed in one piece and can, for example, be produced by metal molding, in particular injection molding, milling, or laser ablation.

For producing the prepackaged power semiconductor 1, the bridge contact element 8 can be placed on the control terminal 4 and on the switching path terminal 3 in such a way that the contact element 6 rests on the switching path terminal 3, and the contact element 7 rests on the control terminal 4. The control terminal 4 and the switching path terminal 3 may have previously been wetted, or coated, by means of a soldering agent 5 or sintering agent. The bridge contact element 8 can then be materially connected, in particular soldered or sintered, to the power transistor 2. In another embodiment, the bridge contact element 8 can be printed, or coated, with solder paste or sinter paste before being placed on the terminals.

The power transistor 2, together with the bridge contact element 8, can then be embedded with a molding compound 44 that is in particular filled with an, in particular large, proportion of particles and/or adapted to the power transistor CTE. After the molding compound 44 has cured, a part 8′ of the bridge contact element 8, together with the molding compound surrounding it, can be cut off along a parting plane 9 shown as a dashed line, so that a contact element 6′ that is galvanically and electrically separated from the control terminal 4 is formed on the switching path terminal 3, and a contact element 7′ that contacts the control terminal 4 and is separated from the switching path terminal 3 is formed on said control terminal. The contact elements 6′ and 7′ are thus flush with a surface of the thus formed prepackaged power semiconductor 1, the surface being formed by the molding compound 44 on the materially electrically connecting, in particular wire bonding, sintering, or soldering, to a rewiring circuit carrier.

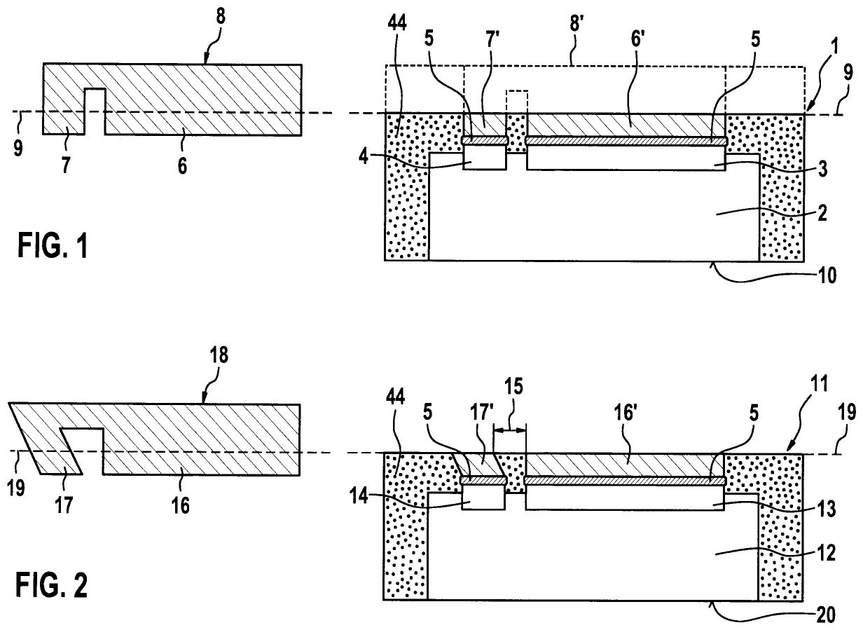

FIG. 2 shows, schematically, an exemplary embodiment of a prepackaged power semiconductor 11, in particular power transistor, which has a housingless power transistor 12 embedded in a molding compound 44. The power transistor 12 has a switching path terminal 13, a control terminal 14, and a further switching path terminal 20. FIG. 2 also shows a bridge contact element 18, which comprises a contact element 17, which in this exemplary embodiment is designed as a parallelepiped with an in particular diamond-shaped cross-section, and a contact element 16, which is cuboidal in this exemplary embodiment, which are in each case connected to one another by a metal bridge. The bridge contact element 18 can be materially connected to the power transistor 12 with a soldering agent 5 or a sintering agent in such a way that the contact element 16 is connected to the switching path terminal 13, and the contact element 17, in particular the parallelepiped-shaped contact element 17, is connected to the control terminal 14. After encapsulating with the molding compound 44, a part of the bridge contact element 18 and the molding compound surrounding it can be cut off, in particular sawn off, ground off, laser-ablated or polished away, along a parting plane 19, so that a distance 15 between the contact element 16′ formed on the switching path terminal 3 and the contact element 17′ formed on the control terminal 14 is enlarged in comparison with the distance formed between the source terminal 13 and the control terminal 14. As a result, a further advantageous contacting can take place at low cost.

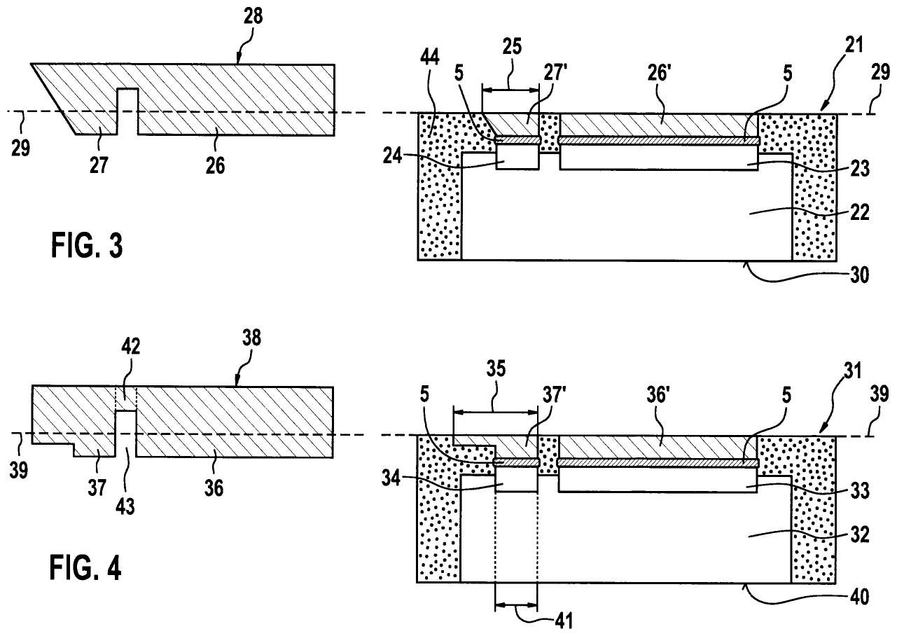

FIG. 3 shows, schematically, an exemplary embodiment for a power semiconductor 21, which has a power transistor 22 with a switching path terminal 23, a control terminal 24, and a further switching path terminal 30. FIG. 3 also shows a bridge contact element 28, which has a cuboidal contact element 26 for connecting to the switching path terminal 23, and a wedge-shaped contact element 27 for connecting to the control terminal 24. After soldering the bridge contact element 28 to the power transistor 22 and cutting off a part of the bridge contact element 28 along the parting plane 29, an outward-facing surface of the contact element 26′ is the same size as a surface of the switching path terminal 23. A surface 25 of the contact element 27′, which is connected to the control terminal 24, is larger than a contact surface of the control terminal 24. Advantageously, the contact element 27′ can be easily accessible by a bonding device, and a bond wire for connecting to the contact element 27′ on the contact surface 25 can, for example, be formed by a bonding strip having a width greater than a largest surface dimension, or surface diameter, of the control terminal 24. The enlargement of the contact surface of the control terminal 24 by the contact element 27′ can be formed independently of the contact surface of the contact element 26′. Unlike as shown in FIG. 3, the outward-facing surface of the contact element 26′ can be larger than, the same size as, or smaller than the surface of the switching path terminal 23.

FIG. 4 shows an exemplary embodiment of a power semiconductor 31, which has a power transistor 32 with a switching path terminal 33, and a control terminal 34, and a further switching path terminal 40, in particular a drain terminal.

FIG. 4 also shows, schematically, a bridge contact element 38, which has a stepped contact element 37 for connecting to the control terminal 34 and a cuboidal contact element 36 designed for contacting the control terminal 33. The contact elements 36 and 37 are in each case connected to one another by means of a connecting portion 42. For this purpose, the bridge contact element 38 has a recess 43 formed between the contact elements 36 and 37. After severing the connecting portion 42, in particular metal bridge, along the parting plane 39, the contact elements 36 and 37 are separated from one another.

An outward-facing contact surface 35 of the cut-off contact element 37′, which is connected to the control terminal 34 by means of a soldering agent 5 or a sintering agent, is larger than a contact surface 41 of the control terminal 34. The contact surface of the contact element 36′, which is cut off from the bridge contact element 38 and materially connected to the switching path terminal 33 by means of the soldering agent 5, is the same size in this exemplary embodiment as the contact surface of the switching path terminal 33.

The contact surface of the contact element 36′, of the contact element 26′, or of the contact element 16′, or of the contact element 6′ can in each case be larger than the contact surface of the control terminal 3, 13, 23, or 33 respectively contacted by them.

The power semiconductors 1, 11, 21, and 31 shown in FIGS. 1, 2, 3, and 4, respectively, can each be produced after encapsulating a wafer or panel comprising a matrix of power transistors, and after cutting off a layer of the wafer that comprises the bridge contact elements, wherein the prepackaged power semiconductors can each be produced after singulation from the molded wafer. Such a method for producing the prepackaged power semiconductor can, for example, take place in a so-called fan-out method. Unlike as described above, the prepackaged power semiconductors 1, 11, 21, or 31 can each be produced in a fan-in method. In this case, side surfaces facing transversely to the electrical terminals can be free of the inner molding compound to the extent that a wafer or panel to be singulated is only covered with inner molding compound from the terminal side in the fan-in method.

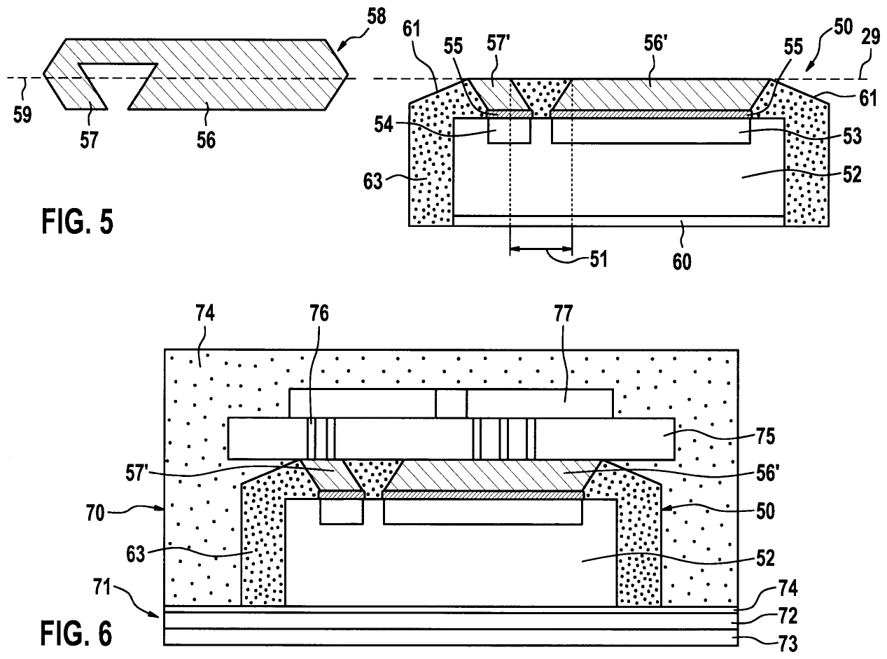

FIG. 5 shows an exemplary embodiment of a power semiconductor 50, which has contact elements 56′ and 57′ respectively produced from a bridge contact element 58. The contact element 56′ is materially connected to a switching path terminal 53 of the power semiconductor 50 by means of a soldering agent 55 or sintering agent, and the contact element 57′ is materially connected to a control terminal 54 by means of the soldering agent or sintering agent 55. A distance 51 between the contact surfaces of the contact elements 56′ and 57′ that are designed to contact the power semiconductor 50 is larger in this exemplary embodiment than a distance or gap extending between the switching path terminal 53 and the control terminal 54.

For this purpose, the contact element 56′ in this exemplary embodiment is parallelepiped-shaped, and the contact element 57′ is polyhedron-shaped, wherein the polyhedron shape in this exemplary embodiment has two surfaces parallel to one another, wherein one of the surfaces parallel to one another is formed for materially bonding to the control terminal 54, and the surface parallel thereto forms a surface of the power semiconductor 50 that is formed for materially connecting, in particular for bonding, soldering, or sintering.

The power semiconductor 50 also has a molded housing 63, which in this exemplary embodiment has a chamfer 61 running around the contact elements 56′ and 57′, which chamfer forms an in particular roof-shaped bevel from an outer boundary of the power semiconductor 50 up to the contact elements 56′ and 57′. The chamfer 61 can, for example, be produced by laser ablation, grinding, or milling. A further switching path terminal 60, in particular drain terminal, formed for connecting to a circuit carrier is free of the molding compound 63 and can thus be materially connected, in particular soldered or sintered.

In another embodiment, the chamfer 61 can be formed by a correspondingly designed mold, in particular a molding tool.

For this purpose, the bridge contact element 58 can be pointed or tapered, starting from the parting plane 59, away from the contact elements 56 and 57, so that it can be easily demolded by means of a molding tool.

FIG. 6 shows, schematically, a molded module 70, which has the power semiconductor 50 already shown in FIG. 5. Alternatively, the molded module 70 can also have a power semiconductor 10, 20, 30, 40 shown in FIGS. 1 to 4. The molded module 70 has a circuit carrier 71 which has an electrically insulating layer 72, in particular a ceramic layer, and an electrically conductive rear layer 73 for contacting a heat sink. The power semiconductor is connected by soldering or by sintering with the further switching path terminal to the circuit carrier 71, in particular an electrically conductive rewiring layer 80 of the circuit carrier 71. The power semiconductor 50 is connected to a driver circuit board 75, which has a driver 77 that is connected to the switching contact element 57′ via through-connection contacts 76. Instead of the driver circuit board 75, a ceramic driver circuit carrier, in particular LTCC circuit carrier (LTCC=low temperature cofired ceramics) or DBC circuit carrier (DBC=direct-bonded copper) can be formed.

The molded module 70 has a molded body which is formed from a molding compound 74 and in which the power semiconductor 50 is embedded together with the circuit carrier 71.

The molding compound 63 forming the molded body of the power semiconductor 50 is different from the molding compound 74 of the molded module. In this exemplary embodiment, the molding compound 74 of the molded module has a smaller proportion of filling particles, in particular ceramic particles, than the molding compound 63 embedding the power semiconductor. The molding compound has, for example, epoxy resin as a matrix material. The molded module forms, for example, a commutation cell for an inverter and has at least one semiconductor switch half-bridge, wherein the semiconductor switch half-bridge has two power semiconductors of the type described above.

1-11. (canceled)

12. A power semiconductor for a commutation cell, the power semiconductor comprising:
a cuboidal power semiconductor switch including a power transistor, including:
a switching path terminal on one side and a further switching path terminal on a side opposite to the switching path terminal,
a control terminal configured to switch the power semiconductor switch, the control terminal being formed at a distance from the switching path terminal, on the one side;
a contact element, connected to the switching path terminal, for the switching path terminal;
a control contact element, connected to the control terminal, for the control terminal; and
a molded housing which covers a part of a surface of the power transistor and/or at least partially covers the one side with the switching path terminal and the control terminal so that an outward-facing contact surface of the contact element and of the control contact element can be contacted from outside;
wherein the power semiconductor switch has a further switching path terminal, which can be contacted from the outside directly.

13. The power semiconductor according to claim 12, wherein the molded body is flush with the contact surface of the contact element and of the control contact element.

14. The power semiconductor according to claim 12, wherein the contact surfaces of the contact element and the control contact element in each case have, on a contactable outer side, a greater distance from one another and/or are in each case larger than terminal surfaces of the control path terminal and the switching path terminal formed on the transistor.

15. The power semiconductor according to claim 12, wherein the contact element and the control contact element each include copper and/or silver.

16. The power semiconductor according to claim 12, wherein the molded body has a bevel toward a side on a surface formed for contacting.

17. The power semiconductor according to claim 12, wherein, after encapsulation, the power transistor is separated from neighboring power transistors by fan-out and are singulated.

18. A molded module comprising:
a circuit carrier and at least one power semiconductor, each of the at least one power semiconductor including:
a cuboidal power semiconductor switch including a power transistor, including:
a switching path terminal on one side and a further switching path terminal on a side opposite to the switching path terminal,
a control terminal configured to switch the power semiconductor switch, the control terminal being formed at a distance from the switching path terminal, on the one side;
a contact element, connected to the switching path terminal, for the switching path terminal;
a control contact element, connected to the control terminal, for the control terminal; and
a molded housing which covers a part of a surface of the power transistor and/or at least partially covers the one side with the switching path terminal and the control terminal so that an outward-facing contact surface of the contact element and of the control contact element can be contacted from outside;
wherein the power semiconductor switch has a further switching path terminal, which can be contacted from the outside directly
wherein the at least power semiconductor is materially connected, by soldering or by sintering, to the circuit carrier, and the at least one power semiconductor and at least a part of the circuit carrier are embedded in a molding compound which is different from a molding compound of the at least one power semiconductor.

19. A method for producing a power semiconductor having a power semiconductor switch, the method comprising the following steps:
placing a bridge contact element electrically bridging terminals of the power semiconductor switch on terminals;
soldering or sintering the bridge contact element to the terminals;
encapsulating the power semiconductor switch, together with the bridge contact element, with a molding compound; and
cutting off a part of the bridge contact element, together with a part of the molding compound embedding the power semiconductor switch, so that separate contact elements are formed on the terminals in each case.

20. The method according to claim 19, wherein the separate contact elements are flush with the molding compound surrounding them.

21. The method according to claim 19, further comprising materially connecting the power semiconductor to a circuit carrier.

22. The method according to claim 21, further comprising:
embedding the power semiconductor, together with the circuit carrier, in a molding compound which is different from the molding compound encapsulating the power semiconductor switch.
